(19) United States
(12) Patent Application Publication
(10) Pub. No.: US 2007/0181534 A1
(43) Pub. Date: Aug. 9, 2007

(54) Barrier polishing liquid and chemical mechanical polishing method

(75) Inventor: Tetsuya Kamimura, Shizuoka (JP)

Correspondence Address: SUGHRUE MION, PLLC, 2100 PENNSYLVANIA AVENUE, N.W., SUITE 800, WASHINGTON, DC, 20037, US

(73) Assignee: FUJIFILM Corporation, Tokyo (JP)

(21) Appl. No.: 11/698,817

(22) Filed: Jan. 29, 2007

(30) Foreign Application Priority Data
Feb. 7, 2006 (JP) 2006-029107

(51) Int. Cl. B24D 3/02; C09K 13/00; B44C 1/22; H01L 21/302; C03C 15/00

(52) U.S. Cl. 216/88; 51/308; 252/79.1; 438/692

(57) ABSTRACT

A barrier polishing liquid is provided that includes (a) a nonionic surfactant represented by Formula (I) below, (b) at least one type of organic acid selected from the group consisting of an aromatic sulfonic acid, an aromatic carboxylic acid, and a derivative thereof, (c) colloidal silica, and (d) benzotriazole or a derivative thereof.

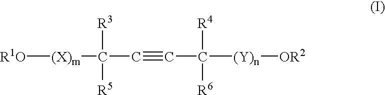

(In Formula (I), R¹ to R⁶ independently denote a hydrogen atom or an alkyl group having 1 to 10 carbons, X and Y independently denote an ethyleneoxy group or a propyleneoxy group, and m and n independently denote an integer of 0 to 20.) There is also provided a chemical mechanical polishing method that includes supplying the barrier polishing liquid to a polishing pad on a polishing platen at a flow rate per unit area of a semiconductor substrate per unit time of 0.035 to 0.25 mL/(min·cm²), and polishing by making the polishing pad and a surface to be polished move relative to each other while they are in a contacted state.

### BACKGROUND OF THE INVENTION

1. Field of the Invention

The present invention relates to a barrier polishing liquid used in the production of a semiconductor device, and a polishing method for carrying out chemical mechanical planarization; in particular, it relates to a barrier polishing liquid that is suitably used for polishing a barrier metal material in planarization in a wiring step for a semiconductor device, and a chemical mechanical polishing method.

2. Description of the Related Art

With regard to the development of semiconductor devices represented by large-scale integrated circuits (hereinafter, denoted by ‘LSI’), in order to achieve small dimensions and high speed there has in recent years been a demand for higher density and higher integration by increasing the fineness and the layering of wiring. As techniques therefor, various techniques such as chemical mechanical polishing (hereinafter, denoted by ‘CMP’) have been employed.

A general CMP method involves affixing a polishing pad to a circular polishing platen, soaking the surface of the polishing pad with a polishing liquid (slurry), pressing the surface of a substrate (wafer) against the pad, and rotating both the polishing platen and the substrate while applying a predetermined pressure (polishing pressure) to the reverse sides thereof, thus planarizing the surface of the substrate by means of the mechanical friction generated. Such a chemical mechanical polishing method is applied, in addition to the formation of wiring, to the formation of capacitors, gate electrodes, etc., and is also utilized when mirror-polishing a silicon wafer such as an SOI (Silicon on Insulator) substrate. Targets for polishing by such a chemical mechanical polishing method include a wide range of substances such as polysilicon film (polycrystalline silicon film), monocrystalline silicon film, silicon oxide film, aluminum, tungsten, and copper.

However, when CMP is carried out, abrasive damage (scratching), a phenomenon in which the entire surface to be polished is abraded more than necessary (thinning), a phenomenon in which the polished surface is not flat and only a central area is deeply polished to form a dish-shaped indentation (dishing), a phenomenon in which an insulator between wires is abraded more than necessary and surfaces of a plurality of metal wires form a dish-shaped recess (erosion), etc. might occur. With regard to an aqueous dispersion for chemical mechanical polishing that suppresses these surface defects such as dishing, various types of compositions have been proposed in the art. For example, a slurry containing a surfactant having a triple bond is excellent in terms of surface smoothness (ref. e.g. JP-A-2002-256256; JP-A denotes a Japanese unexamined patent publication application).

However, hardly any investigation has been carried out into the type, etc. of an organic acid that sufficiently exhibits an effect in an actual formulation.

Furthermore, in recent years, accompanying a decrease in the unit cost of LSI, there has been a strong desire for a chemical mechanical polishing method that can sufficiently suppress the cost in actual use.

### BRIEF SUMMARY OF THE INVENTION

It is an object of the present invention to provide a barrier polishing liquid that enables polishing to proceed at a sufficient polishing rate and dishing to be suppressed in chemical mechanical polishing of a semiconductor device film, etc. that is to be processed.

It is another object of the present invention to provide a chemical mechanical polishing method that, in chemical mechanical polishing of a semiconductor device film, etc. that is to be processed, enables polishing to proceed at a sufficient polishing rate with the use of a small amount of polishing liquid, dishing to be suppressed, and the cost to be sufficiently suppressed in actual use.

As a result of an intensive investigation by the present inventors, it has been found that the above-mentioned problems can be solved by the use of the barrier polishing liquid and the chemical mechanical polishing method below, and the objects have thus been accomplished. That is, the present invention is as described below.

(1) A barrier polishing liquid comprising (a) a nonionic surfactant represented by Formula (I) below, (b) at least one type of organic acid selected from the group consisting of an aromatic sulfonic acid, an aromatic carboxylic acid, and a derivative thereof, (c) colloidal silica, and (d) benzotriazole or a derivative thereof,

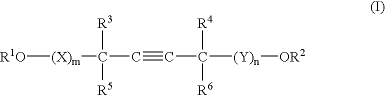

(in Formula (I), R¹ to R⁶ independently denote a hydrogen atom or an alkyl group having 1 to 10 carbons, X and Y independently denote an ethyleneoxy group or a propyleneoxy group, and m and n independently denote an integer of 0 to 20), and
(2) a chemical mechanical polishing method comprising supplying a barrier polishing liquid comprising at least (a) a nonionic surfactant represented by Formula (I) below, (b) at least one type of organic acid selected from the group consisting of an aromatic sulfonic acid, an aromatic carboxylic acid, and a derivative thereof, (c) colloidal silica, and (d) benzotriazole or a derivative thereof to a polishing pad on a polishing platen at a flow rate per unit area of a semiconductor substrate per unit time of 0.035 to 0.25 mL/(min·cm²), and polishing by making the polishing pad and a surface to be polished move relative to each other while they are in a contacted state,

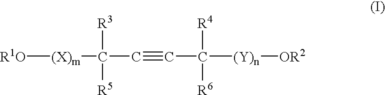

(in Formula (I), R¹ to R⁶ independently denote a hydrogen atom or an alkyl group having 1 to 10 carbons, X and Y independently denote an ethyleneoxy group or a propyleneoxy group, and m and n independently denote an integer of 0 to 20).

### DETAILED DESCRIPTION OF THE INVENTION

Embodiments of the present invention are explained below.

There has until now been the problem that, accompanying a decrease in the flow rate of a polishing liquid used for processing, the cooling effect of the polishing liquid is degraded, and as a result the processing temperature during polishing increases and dishing is worsened. In order to prevent this, there is a desire for a composition for which the polishing rate does not suffer from temperature dependence. As a measure therefor, a formulation could be considered for which a non-temperature dependent action, such as, for example, the action of removing by scratching with particles, is strengthened. However, in a formulation for which the action of removing by scratching with particles, etc. is strengthened, when an insulating film having a low mechanical strength is polished, other problems such as film peeling off or scratching might occur.

It is surmised that, unlike a conventional polishing liquid (slurry), the reason why the above-mentioned various problems can be solved by the present invention is because a nonionic surfactant, an aromatic sulfonic acid or an aromatic carboxylic acid, colloidal silica, and benzotriazole or a derivative thereof are contained therein. That is, the nonionic surfactant adsorbs on the periphery of a polishing particle to thus form a soft film layer on the particle surface. Formation of the soft film layer enables the generation of excessive frictional heat to be suppressed. However, in general, the formation of a soft film layer might cause a reduction in the polishing rate. However, the surface of an insulating film is modified by the aromatic sulfonic acid or aromatic carboxylic acid so that it can be polished by a light action of removing by scratching. In addition, benzotriazole or a derivative thereof acts strongly on a metal of a conductive area, thereby suppressing excessive polishing of the conductive area. This enables the generation of excessive frictional heat to be avoided even at a very low polishing flow rate, and the problem of dishing to be solved.

### Barrier Polishing Liquid

The barrier polishing liquid (hereinafter, also simply called a ‘polishing liquid’) of the present invention is a polishing liquid that can suitably be used when polishing a barrier layer in a semiconductor such as an LSI, and comprises at least a nonionic surfactant represented by Formula (I) above, at least one type of organic acid selected from any one of an aromatic sulfonic acid, an aromatic carboxylic acid, and a derivative thereof, colloidal silica, and benzotriazole or a derivative thereof.

Furthermore, the barrier polishing liquid of the present invention may be used suitably in the chemical mechanical polishing method of the present invention, which will be described later.

(a) Nonionic Surfactant

The polishing liquid of the present invention comprises a nonionic surfactant (a) represented by Formula (I) below.

It is preferable for the polishing liquid to comprise a nonionic surfactant represented by Formula (I) since the generation of excessive frictional heat by polishing particles can be suppressed.

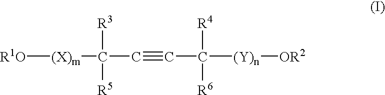

### (In Formula (I), R¹ to R⁶ independently denote a hydrogen atom or an alkyl group having 1 to 10 carbons, X and Y independently denote an ethyleneoxy group or a propyleneoxy group, and m and n independently denote an integer of 0 to 20.)

In Formula (I), R¹ and R² are independently a hydrogen atom or an alkyl group having 1 to 10 carbons, preferably a hydrogen atom, a methyl group, an ethyl group, a propyl group, or an isopropyl group, and more preferably a hydrogen atom.

In Formula (I), R³ to R⁶ are independently a hydrogen atom or an alkyl group having 1 to 10 carbons, preferably a methyl group, an ethyl group, a propyl group, an isopropyl group, a butyl group, or a 2-methylpropyl group, and more preferably a methyl group or a 2-methylpropyl group.

In Formula (I), X and Y are independently an ethyleneoxy group (—CH₂CH₂O—) or a propyleneoxy group (—CH₂CH₂CH₂O—, —CH₂CH(CH₃)O—, or —CH(CH₃)CH₂O—), preferably —CH₂CH₂O—, —CH₂CH(CH₃)O—, or —CH(CH₃)CH₂O—, and more preferably —CH₂CH₂O—. Furthermore, as described later, it is also preferable that m or n is independently 0 and the corresponding X or Y is a single bond.

Moreover, when X and/or Y is a propyleneoxy group, and the corresponding m or n is at least 2, the above-mentioned propyleneoxy structures may be present in combination. The ethyleneoxy group and the propyleneoxy group denoted by X or Y are connected to R¹O— or R²⁰— via a carbon atom.

In Formula (I), m and n are independently integers of 0 to 20.

In Formula (I), when m and/or n are 0, the corresponding X and/or Y denote a single bond.

As the above-mentioned nonionic surfactant, those having the following structure can be cited as preferred examples. In addition, m and n in W-2 below independently denote any integer of 1 to 20.

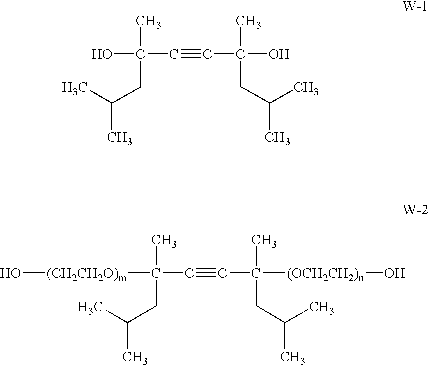

The above-mentioned nonionic surfactant may be synthesized by a known method, but a commercial product may be used.

The amount of compound represented by Formula (I) added is, as a total weight, preferably 0.01 to 5 wt % in the barrier polishing liquid when used for polishing, and more preferably 0.05 to 3 wt %. It is preferable for the amount added to be in the above-mentioned range since a sufficient effect can be exhibited and good storage stability can be achieved.

(b) Organic Acid

The polishing liquid of the present invention comprises at least one type of (b) organic acid selected from the group consisting of an aromatic sulfonic acid, an aromatic carboxylic acid, or a derivative thereof. Examples of the derivative include an ester compound, an amide compound, an acid anhydride, an ammonium salt, an alkali metal salt, and an alkaline earth metal compound of the aromatic sulfonic acid and aromatic carboxylic acid.

It is preferable for the polishing liquid of the present invention to comprise any one of the aromatic sulfonic acid, the aromatic carboxylic acid, or the derivative thereof since excessive frictional heat can be suppressed during polishing.

Preferred examples of the organic acid include p-toluenesulfonic acid, p-toluenesulfonic acid amide, methyl p-toluenesulfonate, ethyl p-toluenesulfonate, p-toluenesulfonic acid anhydride, toluene-2,α-dicarboxylic acid, pyridinium p-toluenesulfonate, benzoic acid, ammonium benzoate, n-amyl benzoate, vinyl benzoate, methyl benzoate, ethyl benzoate, benzoic acid anhydride, phthalic acid, methyl phthalate, methyl isophthalate, methyl terephthalate, benzenesulfonic acid monohydrate, methyl benzenesulfonate, 1,2,4,5-benzenetetracarboxylic acid, 1,2,3-benzenetricarboxylic acid, phenylglycine, anilinesulfonic acid, N-anilinoacetic acid, sodium o-hydroxybenzoate (sodium salicylate), potassium o-hydroxybenzoate, sodium 5-sulfo-2-hydroxybenzoate (sodium 5-sulfosalicylate), potassium 5-sulfo-2-hydroxybenzoate (potassium 5-sulfosalicylate), anthranilic acid, aminotoluic acid, and quinaldic acid, and among them p-toluenesulfonic acid, ammonium benzoate, phthalic acid, 1,2,4,5-benzenetetracarboxylic acid, and 1,2,3-benzenetricarboxylic acid may particularly preferably be used. These organic acids may be used singly or in a combination of two or more types.

The amount of organic acid added is preferably 0.01 to 20 wt % relative to the total weight of the polishing liquid, more preferably 0.1 to 10 wt %, yet more preferably 0.1 to 5 wt %, and particularly preferably 0.5 to 3 wt %. It is preferable for the amount added to be in the above-mentioned range since a sufficient effect can be exhibited and good storage stability can be achieved.

(c) Polishing Particles

The polishing liquid of the present invention comprises as a constituent (c) colloidal silica. It is preferable for the polishing liquid to comprise colloidal silica since a sufficient polishing rate can be achieved.

Furthermore, in addition to the colloidal silica, other polishing particles may be used in combination. Examples of the polishing particles that can be used in this way include fumed silica, alumina, ceria, titania, zirconia, oxides and nitrides of manganese, chromium, iron, tin, tantalum, etc., and composite particles thereof. Depending on the intended application, hard particles such as diamond might be used. Furthermore, organic particles of polystyrene, acrylic resin, methacrylic resin, methacrylate resin, polyethylene, polypropylene, polyvinylpyrrolidone, polyurethane, PVC, PVA (PVF), phenol resin, epoxy resin, silicone resin, etc. may be used effectively.

The above-mentioned colloidal silica particles may be prepared by, for example, subjecting a silicon alkoxide compound such as Si(OC₂H₅)₄, Si(sec-OC₄H₉)₄, Si(OCH₃)₄, or Si(OC₄H₉)₄ to hydrolysis by a sol-gel method. Such colloidal silica particles are preferable since they have a very sharp particle size distribution.

The average particle size of the colloidal particles means a particle size at the 50% cumulative frequency point in a cumulative particle size curve showing the relationship between the particle size of the colloidal particles and the cumulative frequency obtained by counting the numbers of particles having that particle size. The particle size of the colloidal particles denotes the average particle size obtained in a particle size distribution by a dynamic light scattering method. For example, as a measurement system for obtaining a particle size distribution, an LB-500 manufactured by Horiba, Ltd., etc. may be used.

The average particle size of the colloidal silica particles contained is preferably 5 to 60 nm, and more preferably 5 to 30 nm. In order to achieve a sufficient polishing rate, particles of at least 5 nm are preferable. Furthermore, in order to prevent the generation of excessive frictional heat during polishing, the particle size is preferably at most 60 nm.

It is preferable for the polishing particles to be contained at a concentration of 0.5 to 15 wt % of the polishing liquid, and more preferably 1 to 10 wt %. In order to achieve a sufficient polishing rate, the concentration is preferably at least 0.5 wt %. Furthermore, in order to prevent the generation of excessive frictional heat during polishing, the concentration thereof is at most 15 wt %.

(d) Corrosion Inhibitor

The polishing liquid of the present invention comprises (d) at least one type of benzotriazole or a derivative thereof as a corrosion inhibitor that can form a passivated film on a metal surface that is to be polished and suppress a chemical reaction on a substrate. It is preferable for the polishing liquid to comprise benzotriazole or a derivative thereof since the polishing liquid can then suppress excessive dishing.

The benzotriazole derivative referred to here is a compound in which a hydrogen atom of an aromatic ring of benzotriazole or the hydrogen atom of a hydroxy group thereof is substituted with any organic group. Moreover, the number of substituents possessed by the benzotriazole derivative may be one or more.

Preferred examples of the corrosion inhibitor include 1,2,3-benzotriazole (BTA), 5,6-dimethyl-1,2,3-benzotriazole (DBTA), 1-(1,2-dicarboxyethyl)benzotriazole (DCEBTA), 1-[N,N-bis(hydroxyethyl)aminomethyl]benzotriazole (HEABTA), 1-(hydroxymethyl)benzotriazole (HMBTA), 1-dihydroxypropylbenzotriazole, 2,3-dicarboxypropylbenzotriazole, 4-hydroxybenzotriazole, 4-carboxyl-1H-benzotriazole, 4-methoxycarbonyl-1H-benzotriazole, 4-butoxycarbonyl-1H-benzotriazole, 4-octyloxycarbonyl-1H-benzotriazole, 5-hexylbenzotriazole, N-(1,2,3-benzotriazolyl-1-methyl)-N-(1,2,4-triazolyl-1-methyl)-2-ethylhexylamine, 4-carboxyl-1H-benzotriazole butyl ester, tolyltriazole, naphthotriazole, and bis[(1-benzotriazolyl)methyl]phosphonic acid, and BTA, DBTA, DCEBTA, HEABTA, and HMBTA are more preferable.

The benzotriazole or derivative thereof that can be used in the present invention may be used singly or in a combination of two or more types. Furthermore, the benzotriazole or derivative thereof that can be used in the present invention may be synthesized by a standard method, or a commercial product may be used.

Furthermore, the amount of corrosion inhibitor added is preferably at least 0.01 wt % but no greater than 0.2 wt % of the total weight of the polishing liquid, and more preferably at least 0.05 wt % but no greater than 0.2 wt %.

Moreover, the polishing liquid of the present invention may comprise a dispersion medium and another component, and preferred examples of said other component include an oxidizing agent, an acid, a chelating agent, an additive, a surfactant, a hydrophilic polymer, an alkali agent, and a buffering agent. As the above-mentioned component that the polishing liquid comprises, there may be employed one type, or two or more types in combination.

### Oxidizing Agent

The polishing liquid of the present invention preferably comprises a compound (oxidizing agent) that can oxidize a polishing target metal.

Examples of the oxidizing agent include hydrogen peroxide, a peroxide, a nitrate, an iodate, a periodate, a hypochlorite, a chlorite, a chlorate, a perchlorate, a persulfate, a dichromate, a permanganate, ozone water, a silver (II) salt, and an iron (III) salt.

Preferred examples of the iron (III) salt include inorganic iron (III) salts such as iron (III) nitrate, iron (III) chloride, iron (III) sulfate, and iron (III) bromide, and organic complex salts of iron (III).

When an organic complex salt of iron (III) is used, with regard to complex-forming compounds forming an iron (III) complex salt, examples thereof include acetic acid, citric acid, oxalic acid, salicylic acid, diethyldithiocarbamic acid, succinic acid, tartaric acid, glycolic acid, glycine, alanine, aspartic acid, thioglycolic acid, ethylene diamine, trimethylene diamine, diethylene glycol, triethylene glycol, 1,2-ethanedithiol, malonic acid, glutaric acid, 3-hydroxybutyric acid, propionic acid, phthalic acid, isophthalic acid, 3-hydroxysalicylic acid, 3,5-dihydroxysalicylic acid, gallic acid, benzoic acid, maleic acid, salts thereof, and an aminopolycarboxylic acid and a salt thereof.

Examples of the aminopolycarboxylic acid and the salt thereof include ethylenediamine-N,N,N′,N′-tetraacetic acid, diethylenetriaminepentaacetic acid, 1,3-diaminopropane-N,N,N′,N′-tetraacetic acid, 1,2-diaminopropane-N,N,N N′-tetraacetic acid, ethylenediamine-N,N′-disuccinic acid (racemate), ethylenediaminedisuccinic acid (SS form), N-(2-carboxylatoethyl)-L-aspartic acid, N-(carboxymethyl)-L-aspartic acid, β-alaninediacetic acid, methyliminodiacetic acid, nitrilotriacetic acid, cyclohexanediaminetetraacetic acid, iminodiacetic acid, glycol ether diaminetetraacetic acid, ethylenediamine-N,N′-diacetic acid, ethylenediamine-ortho-hydroxyphenylacetic acid, N,N-bis(2-hydroxybenzyl)ethylenediamine-N,N-diacetic acid, and salts thereof. The type of counter salt is preferably an alkali metal salt or an ammonium salt, and particularly preferably an ammonium salt.

Among them, hydrogen peroxide, an iodate, a hypochlorite, a chlorate, a persulfate, and an organic complex salt of iron (III) are preferable; when an organic complex salt of iron (III) is used, preferred examples of the complex-forming compounds include citric acid, tartaric acid, and an aminopolycarboxylic acid (specifically, ethylenediamine-N,N,N N′-tetraacetic acid, diethylenetriaminepentaacetic acid, 1,3-diaminopropane-N,N,N,N′-tetraacetic acid, ethylenediamine-N,N′-disuccinic acid (racemate), ethylenediaminedisuccinic acid (SS form), N-(2-carboxylatoethyl)-L-aspartic acid, N-(carboxymethyl)-L-aspartic acid, β-alaninediacetic acid, methyliminodiacetic acid, nitrilotriacetic acid, or iminodiacetic acid).

Among the oxidizing agents, hydrogen peroxide, a persulfate, and ethylenediamine-N,N,N′,N′-tetraacetic acid, 1,3-diaminopropane-N,N,N,N′-tetraacetic acid, and ethylenediaminedisuccinic acid (SS form) complexes of iron (III) are most preferable.

The amount of oxidizing agent added is preferably 0.003 mol to 8 mol per L of the metal polishing liquid when used for polishing, more preferably 0.03 mol to 6 mol, and particularly preferably 0.1 mol to 4 mol. That is, the amount of oxidizing agent added is preferably at least 0.003 mol/L from the viewpoint of oxidation of the metal being adequate and a high CMP rate being guaranteed, and no greater than 8 mol/L from the viewpoint of preventing the polished surface from becoming rough.

### Acid

The polishing liquid of the present invention preferably further comprises an acid. The acid referred to here is a compound having a structure that is different from the oxidizing agent that is for oxidizing the metal, and does not include an acid that functions as the above-mentioned oxidizing agent. The acid here has the actions of oxidation promotion, pH adjustment, and buffering. Examples of the acid include those in the categories of inorganic acids, organic acids other than the above-mentioned organic acids, and amino acids. Examples of the inorganic acids include sulfuric acid, nitric acid, boric acid, phosphoric acid, and carbonic acid, and among the inorganic acids phosphoric acid and carbonic acid are preferable.

In the present invention, it is particularly preferable for an organic acid other than the above-mentioned organic acids to be present. As the organic acid, those selected from the group below are more suitable. There can be cited formic acid, acetic acid, propionic acid, butyric acid, valeric acid, 2-methylbutyric acid, n-hexanoic acid, 3,3-dimethylbutyric acid, 2-ethylbutyric acid, 4-methylpentanoic acid, n-heptanoic acid, 2-methylhexanoic acid, n-octanoic acid, 2-ethylhexanoic acid, glycolic acid, glyceric acid, oxalic acid, malonic acid, succinic acid, glutaric acid, adipic acid, pimelic acid, maleic acid, malic acid, tartaric acid, citric acid, lactic acid, and salts thereof such as ammonium salts or alkali metal salts, and mixtures thereof. Among them, formic acid, malonic acid, malic acid, tartaric acid, and citric acid are suitable for a laminate film comprising at least one type of metal layer selected from copper, a copper alloy, and an oxide of copper or a copper alloy.

The amount of acid added is preferably 0.0005 mol to 0.5 mol in 1 L of the polishing liquid when used for polishing, more preferably 0.005 mol to 0.3 mol, and particularly preferably 0.01 mol to 0.1 mol. That is, the amount of acid added is preferably at most 0.5 mol/L from the viewpoint of suppression of etching, and at least 0.0005 mol/L in order to obtain a sufficient effect.

### Chelating Agent

The polishing liquid of the present invention preferably comprises a chelating agent (i.e. a water softener) as necessary in order to reduce the adverse influence of a polyvalent metal ion, etc. contaminant. The chelating agent is a commonly used water softener or an analogue thereof, that is, a precipitation-preventing agent for calcium or magnesium, and examples thereof include nitrilotriacetic acid, diethylenetriaminepentaacetic acid, ethylenediaminetetraacetic acid, N,N,N-trimethylenephosphonic acid, ethylenediamine-N,N,N′,N′-tetramethylenesulfonic acid, trans-cyclohexanediaminetetraacetic acid, 1,2-diaminopropanetetraacetic acid, glycol ether diaminetetraacetic acid, ethylenediamine-ortho-hydroxyphenylacetic acid, ethylenediaminedisuccinic acid (SS form), N-(2-carboxylatoethyl)-L-aspartic acid, β-alaninediacetic acid, 2-phosphonobutane-1,2,4-tricarboxylic acid, 1-hydroxyethylidene-1,1-diphosphonic acid, and N,N′-bis(2-hydroxybenzyl)ethylenediamine-N,N′-diacetic acid.

The chelating agent may be used as a combination of two or more types as necessary. The amount of chelating agent added may be any amount as long as it is sufficient to sequester a metal ion contaminant such as a polyvalent metal ion, and it is added at, for example, 0.0003 mol to 0.07 mol in 1 L of the polishing liquid when used for polishing.

### Additive

The polishing liquid of the present invention preferably uses the additives below.

Ammonia; an alkylamine such as dimethylamine, trimethylamine, triethylamine, or propylenediamine, or an amine such as ethylenediaminetetraacetic acid (EDTA), sodium diethyldithiocarbamate, or chitosan; an imine such as dithizone, cuproine (2,2′-biquinoline), neocuproine (2,9-dimethyl-1,10-phenanthroline), bathocuproine (2,9-dimethyl-4,7-diphenyl-1,10-phenanthroline), or cuperazone (biscyclohexanone oxalylhydrazone); an azole such as benzimidazole-2-thiol, 2-[2-(benzothiazolyl)]thiopropionic acid, 2-[2-(benzothiazolyl)]thiobutyric acid, 2-mercaptobenzothiazole, 1,2,3-triazole, 1,2,4-triazole, or 3-amino-1H-1,2,4-triazole; a mercaptan such as nonylmercaptan, dodecylmercaptan, triazinethiol, triazinedithiol, or triazinetrithiol, and others such as L-tryptophan. Among them chitosan, ethylenediaminetetraacetic acid, L-tryptophan, cuperazone, and triazinedithiol are particularly preferable from the viewpoint of achieving a balance between a high CMP rate and a low etching rate.

The amount of additive added is preferably 0.0001 mol to 0.5 mol in 1L of the polishing liquid when used for polishing, more preferably 0.001 mol to 0.2 mol, and particularly preferably 0.005 mol to 0.1 mol. That is, the amount of additive added is preferably at least 0.0001 mol/L from the viewpoint of etching being suppressed, and no greater than 0.5 mol/L from the viewpoint of preventing the CMP rate from being degraded.

### Surfactant and Hydrophilic Polymer

The polishing liquid of the present invention may comprise a surfactant and/or a hydrophilic polymer other than the surfactant represented by Formula (1) above. The surfactant and the hydrophilic polymer both have a function of decreasing the contact angle of the surface to be polished and a function of promoting uniform polishing. The surfactant and/or the hydrophilic polymer used here are preferably selected from the group below.

Examples of anionic surfactants include a carboxylate salt, a sulfonate salt, a sulfate ester, and a phosphate ester; examples of the carboxylate salt include a soap, an N-acylamino acid salt, a polyoxyethylene or polyoxypropylene alkyl ether carboxylate, and an acylated peptide; examples of the sulfonate salt include an alkylsulfonate salt, a sulfosuccinate salt, an α-olefinsulfonate salt, and an N-acylsulfonate salt; examples of the sulfate ester include a sulfated oil, an alkylsulfate salt, an alkyl ether sulfate salt, a polyoxyethylene or polyoxypropylene alkyl aryl ether sulfate salt, and an alkylamide sulfate salt; and examples of the phosphate ester include an alkyl phosphate, and a polyoxyethylene or polyoxypropylene alkyl aryl ether phosphate.

Examples of cationic surfactants include an aliphatic amine salt, an aliphatic quaternary ammonium salt, a benzalkonium chloride salt, benzethonium chloride, a pyridinium salt, and an imidazolinium salt; and examples of amphoteric surfactants include a carboxybetaine type, an aminocarboxylate, an imidazolinium betaine, lecithin, and an alkylamine oxide.

Examples of nonionic surfactants include an ether type, an ether ester type, an ester type, and a nitrogen-containing type; specific examples of the ether type include polyoxyethylene alkyl and alkylphenyl ethers, an alkyl aryl formaldehyde condensed polyoxyethylene ether, a polyoxyethylene polyoxypropylene block polymer, and a polyoxyethylene polyoxypropylene alkyl ether, specific examples of the ether ester type include a polyoxyethylene ether of a glycerol ester, a polyoxyethylene ether of a sorbitan ester, and a polyoxyethylene ether of a sorbitol ester, specific examples of the ester type include a polyethylene glycol fatty acid ester, a glycerol ester, a polyglycerol ester, a sorbitan ester, a propylene glycol ester, and a sucrose ester, and specific examples of the nitrogen-containing type include a fatty acid alkanol amide, a polyoxyethylene fatty acid amide, and a polyoxyethylene alkyl amide. Fluorine-based surfactants, etc. can also be cited as examples.

Furthermore, examples of other surfactants, hydrophilic compounds, hydrophilic polymers, etc. include esters such as a glycerol ester, a sorbitan ester, methoxyacetic acid, ethoxyacetic acid, 3-ethoxypropionic acid, and an alanine ethyl ester; ethers such as polyethylene glycol, polypropylene glycol, polytetramethylene glycol, a polyethylene glycol alkyl ether, a polyethylene glycol alkenyl ether, an alkyl polyethylene glycol, an alkyl polyethylene glycol alkyl ether, an alkyl polyethylene glycol alkenyl ether, an alkenyl polyethylene glycol, an alkenyl polyethylene glycol alkyl ether, an alkenyl polyethylene glycol alkenyl ether, a polypropylene glycol alkyl ether, a polypropylene glycol alkenyl ether, an alkyl polypropylene glycol, an alkyl polypropylene glycol alkyl ether, an alkyl polypropylene glycol alkenyl ether, an alkenyl polypropylene glycol, an alkenyl polypropylene glycol alkyl ether, and an alkenyl polypropylene glycol alkenyl ether; polysaccharides such as alginic acid, pectic acid, carboxymethylcellulose, curdlan, and pullulan; amino acid salts such as glycine ammonium salt and glycine sodium salt; polycarboxylic acids and salts thereof such as polyaspartic acid, polyglutamic acid, polylysine, polymalic acid, polymethacrylic acid, ammonium polymethacrylate, sodium polymethacrylate, polymaleic acid, polyitaconic acid, polyfumaric acid, poly(p-styrenecarboxylic acid), polyacrylic acid, polyacrylamide, aminopolyacrylamide, ammonium polyacrylate, sodium polyacrylate, polyamide acid, ammonium polyamide, sodium polyamide, and polyglyoxylic acid; vinyl-based polymers such as polyvinyl alcohol, polyvinylpyrrolidone, and polyacrolein; ammonium methyltaurinate, sodium methyltaurinate, sodium methyl sulfate, ammonium ethyl sulfate, ammonium butyl sulfate, sulfonic acids and salts thereof such as sodium vinylsulfonate, sodium 1-allylsulfonate, sodium 2-allylsulfonate, sodium methoxymethylsulfonate, ammonium ethoxymethylsulfonate, sodium 3-ethoxypropylsulfonate, sodium methoxymethylsulfonate, ammonium ethoxymethylsulfonate, sodium 3-ethoxypropylsulfonate, and sodium sulfosuccinate; amides such as propionamide, acrylamide, methylurea, nicotinamide, succinamide, and sulfanilamide; and alcohols such as cyclohexanol.

When an object to be polished to which the present invention is applied is a large-scale integrated circuit silicon substrate, etc., since contamination by an alkali metal, an alkaline earth metal, a halide, etc. is undesirable, an acid or an ammonium salt thereof is preferable. When the substrate is a glass substrate, etc., this does not apply. Among the above-mentioned compound examples, cyclohexanol, ammonium polyacrylate, polyvinyl alcohol, succinamide, polyvinylpyrrolidone, polyethylene glycol, and a polyoxyethylene polyoxypropylene block polymer are more preferable.

The amount of surfactant and hydrophilic polymer added is preferably 0.001 to 10 g in 1 L of the polishing liquid when used for polishing, more preferably 0.01 to 5 g, and particularly preferably 0.1 to 3 g. That is, the amount of surfactant and hydrophilic polymer added is preferably at least 0.001 g/L from the viewpoint of a sufficient effect being exhibited, and no greater than 10 g/L from the viewpoint of preventing the CMP rate from being degraded. Furthermore, these hydrophilic polymers preferably have a weight-average molecular weight of 500 to 100,000, and particularly preferably 2,000 to 50,000.

### Alkali Agent and Buffering Agent

The polishing liquid of the present invention may comprise as necessary an alkali agent for adjustment of the pH, and a buffering agent from the viewpoint of suppressing variation in the pH.

Examples of the alkali agent (or the buffering agent) include non-metallic alkali agents such as ammonium hydroxide, organic ammonium hydroxides such as tetramethylammonium hydroxide, alkanolamines such as diethanolamine, triethanolamine, and triisopropanolamine, alkali metal hydroxides such as sodium hydroxide, potassium hydroxide, and lithium hydroxide, a carbonate salt, a phosphate salt, a borate salt, a tetraborate salt, a glycyl salt, an N,N-dimethylglycine salt, a leucine salt, a norleucine salt, a guanine salt, a 3,4-dihydroxyphenylalanine salt, an alanine salt, an aminobutyrate salt, a 2-amino-2-methyl-1,3-propanediol salt, a valine salt, a proline salt, a trishydroxyaminomethane salt, and a lysine salt.

Specific examples of the alkali agent (or the buffering agent) include sodium hydroxide, potassium hydroxide, lithium hydroxide, sodium carbonate, potassium carbonate, sodium bicarbonate, potassium bicarbonate, trisodium phosphate, tripotassium phosphate, disodium phosphate, dipotassium phosphate, sodium borate, potassium borate, sodium tetraborate (borax), potassium tetraborate, ammonium hydroxide, and tetramethylammonium hydroxide.

Furthermore, particularly preferred alkali agents are ammonium hydroxide, potassium hydroxide, lithium hydroxide, and tetramethylammonium hydroxide.

The amount of alkali agent (or buffering agent) added may be any amount as long as the pH is maintained in a preferred range, and it is preferably 0.0001 mol to 1.0 mol in 1 L of the polishing liquid when used for polishing, and more preferably 0.003 mol to 0.5 mol.

The polishing liquid when used for polishing preferably has a pH of 2 to 14, and more preferably a pH of 3 to 12. In this range, the polishing liquid of the present invention exhibits particularly superior effects.

### Dispersion Medium

As the dispersion medium for the polishing liquid that can be used in the present invention, water alone or a mixture of water as a main component (50 to 99 wt % in the dispersion medium) and a water-soluble organic solvent such as an alcohol or a glycol as an auxiliary component (1 to 30 wt %) may be used.

The water is preferably pure water or ion-exchanged water that contains as few macroparticles as possible.

Examples of the alcohol include methyl alcohol, ethyl alcohol, and isopropyl alcohol, and examples of the glycol include ethylene glycol, tetramethylene glycol, diethylene glycol, propylene glycol, and polyethylene glycol.

The content of the dispersion medium in the polishing liquid is preferably 75 to 95 wt %, and more preferably 85 to 90 wt %. It is preferably at least 75 wt % from the viewpoint of supply of the polishing liquid onto a substrate.

With regard to the polishing liquid of the present invention, when polishing, it is preferable to appropriately select the type of compound, the amount thereof added, the pH, and the dispersion medium according to adsorption properties and reactivity toward the polishing surface, the solubility of the metal to be polished, electrochemical properties of the surface to be polished, the state in which a compound functional group is dissociated, and the stability as a liquid.

Among components that are added when preparing a concentrate of the polishing liquid, the amount added of a component that has a solubility in a solvent at room temperature of less than 5% is preferably no greater than 2 times the solubility in the solvent at room temperature, and more preferably no greater than 1.5 times. If the amount thereof added were equal to or greater than 2 times, it would be difficult to prevent precipitation when the concentrate is cooled to 5° C.

### Chemical Mechanical Polishing Method

The chemical mechanical polishing method of the present invention (hereinafter, also simply called a ‘polishing method’) is a method in which a barrier polishing liquid comprising at least (a) a nonionic surfactant represented by Formula (I) above, (b) at least one type of organic acid selected from the group consisting of an aromatic sulfonic acid, an aromatic carboxylic acid, and a derivative thereof, (c) colloidal silica, and (d) benzotriazole or a derivative thereof, that is, the barrier polishing liquid of the present invention, is supplied to a polishing pad on a polishing platen at a flow rate per unit area of semiconductor substrate per unit time of 0.035 to 0.25 mL/(min·cm²), and polishing is carried out by making the polishing pad and a surface that is to be polished move relative to each other while they are in a contacted state and, for example, as an object that is to be polished, there is a wafer (semiconductor substrate) having a conductive material film (e.g. a metal layer) formed thereon that is planarized chemically and mechanically.

The polishing method of the present invention may suitably be employed in polishing when producing a semiconductor substrate equipped with a barrier layer, and the barrier layer or an insulating film may particularly suitably be polished when producing a semiconductor substrate.

Furthermore, the polishing method of the present invention is preferable since a sufficient polishing rate can be achieved with an amount of polishing liquid that is smaller than the amount of polishing liquid used when polishing is carried out in the art and with a flow rate of the polishing liquid per unit area of semiconductor substrate per unit time of 0.035 to 0.25 mL/(min·cm²), and dishing can be suppressed. Moreover, since the amount of polishing liquid used when polishing is small, this method is an excellent polishing method in terms of cost.

The polishing liquid of the present invention may be applied to a case in which it is used without dilution, a case in which the polishing liquid is formed as a concentrate and it may be used by diluting it with water in actual use, and a case in which each component is prepared in the form of an aqueous solution, which will be described later, they are mixed and diluted with water as necessary in actual use or mixed to give a liquid for actual use. The polishing method of the present invention may be applied to any of these cases, and it is a polishing method in which the polishing liquid is supplied to a polishing pad on a polishing platen and polishing is carried out by making a surface that is to be polished and a polishing pad move relative to each other while they are in a contacted state.

As a polishing system, a standard polishing system comprising a holder for retaining an object that is to be polished such as a semiconductor substrate having a surface to be polished, and a polishing platen (equipped with a motor, etc. that can vary the rotational speed) with a polishing pad affixed thereto can be used. As the polishing pad, a normal nonwoven cloth, a foamed polyurethane, a porous fluorine resin, etc. may be used and there are no particular restrictions. There are no restrictions on the polishing conditions, but the rotational speed of the polishing platen is preferably a low speed of 200 rpm or less so that the substrate will not fly out. The pressure with which a semiconductor substrate having a surface to be polished (a film to be polished) is pressed against the polishing pad is preferably 0.68 to 34.5 KPa, and it is more preferably 3.40 to 20.7 KPa in order to satisfy requirements for in-plane uniformity of the polishing rate for the object that is to be polished (wafer) and pattern planarity.

For example, the semiconductor substrate (object to be polished) after completion of polishing may be washed well with running water and then dried after spinning off water droplets attached to the semiconductor substrate by means of a spin dryer, etc. In the polishing method of the present invention, an aqueous solution for dilution is the same as an aqueous solution described below.

The aqueous solution is water containing in advance at least one of an oxidizing agent, an acid, an additive, and a surfactant, and it is arranged so that the total components of components contained in the aqueous solution and components of the polishing liquid to be diluted are the components for polishing using the polishing liquid. When used by diluting with an aqueous solution, a component that is difficult to dissolve may be added in the form of an aqueous solution, and a more concentrated polishing liquid can be prepared.

As a method for diluting the concentrated polishing liquid by the addition of water or an aqueous solution, there can be cited, for example, a method in which a pipe for supplying the concentrated polishing liquid and a pipe for supplying water or an aqueous solution are combined partway along for mixing, and the mixed diluted polishing liquid is supplied to a polishing pad. Mixing may be carried out by employing a standard method such as, for example, a method in which liquids are made to collide with each other through a narrow passage in a pressurized state, a method in which the pipe is packed with a packing such as glass tubes and the flow of liquid is repeatedly divided, separated, and combined, or a method in which a blade that is rotated by a motor is provided in the pipe.

As a method for polishing by diluting the concentrated polishing liquid with water or an aqueous solution, for example, a method can be used in which a pipe for supplying the polishing liquid and a pipe for supplying water or an aqueous solution are provided independently, and polishing is carried out while supplying a predetermined amount of liquid to a polishing pad from each pipe and mixing by relative movement between the polishing pad and a surface to be polished. Furthermore, there is, for example, a method in which predetermined amounts of concentrated polishing liquid and water or an aqueous solution are added to one container and mixed, this mixed polishing liquid is supplied to a polishing pad, and polishing is carried out.

As another polishing method of the present invention there can be cited, for example, a method in which the components that are to be contained in the polishing liquid are divided into at least two constituents, when they are used they are diluted by the addition of water or an aqueous solution and supplied to a polishing pad on a polishing platen so as to contact a surface to be polished, and polishing is carried out by relative movement between the surface to be polished and the polishing pad. For example, Constituent (A) comprises an oxidizing agent, Constituent (B) comprises an acid, an additive, a surfactant, and water, and when used Constituent (A) and Constituent (B) are preferably diluted with water or an aqueous solution.

Alternatively, the additives that have low solubility are divided into two, that is, Constituents (A) and (B), Constituent (A) comprises an oxidizing agent, an additive, and a surfactant, and Constituent (B) comprises an acid, an additive, a surfactant, and water, and when used Constituent (A) and Constituent (B) are preferably dissolved in or diluted with water or an aqueous solution. In the case of this example, it is necessary to employ three pipes for supplying Constituent (A), Constituent (B), and water or an aqueous solution, and dilution and mixing are carried out by a method in which the three pipes are combined into one pipe for supplying to a polishing pad, and mixing is carried out within the pipe, and in this case two pipes may be combined and then combined with the other pipe.

For example, there is a method in which a constituent containing an additive that is difficult to dissolve is mixed with another constituent, the mixing path is made long so as to ensure that there is a long dissolution time, and a pipe for water or an aqueous solution is further combined therewith. With regard to another mixing method, for example, there are a method in which as described above three pipes are directly guided to a polishing pad, and mixing is carried out by relative movement between the polishing pad and a surface to be polished, and a method in which three constituents are mixed in one container, and the diluted polishing liquid is supplied therefrom to a polishing pad. In the above-mentioned polishing methods, one constituent containing an oxidizing agent is maintained at 40° C. or less, the other constituent is heated at a temperature in the range of room temperature to 100° C., and when said one constituent and said other constituent are used by dilution with water or an aqueous solution, the temperature of the mixture is made to be 40° C. or less. This is a preferred method in order to increase the solubility of a starting material having a low solubility in the polishing liquid since the solubility increases when the temperature is high.

A starting material that is dissolved by heating said other constituent containing no oxidizing agent at a temperature in the range of room temperature to 100° C. precipitates in the solution when the temperature decreases, and when the constituent whose temperature has decreased is used, it is necessary to heat it in advance so as to dissolve the precipitate. This is preferably achieved by employing means for feeding a liquid that has a heated and dissolved constituent and means for stirring a liquid containing a precipitate, feeding the liquid, and dissolving by heating a pipe. Since there is a possibility that, if the heated constituent increases the temperature of a constituent containing an oxidizing agent to 40° C. or higher, the oxidizing agent might decompose, it is preferable to set the temperature at 40° C. or less when mixing the heated constituent and said one constituent containing an oxidizing agent for cooling said heated constituent.

Furthermore, in the present invention, as described above, components of the polishing liquid may be divided into two or more and supplied to the polishing surface. In this case, it is preferable to divide them into a constituent containing an oxide and a constituent containing an acid. It is also possible to prepare the polishing liquid as a concentrate and supply water for dilution separately to the polishing surface. In the present invention, the amount supplied in these cases is the total of the amounts supplied from each pipe.

### Polishing Liquid Flow Rate

The polishing liquid flow rate in the polishing method of the present invention is defined as the flow rate of polishing liquid supplied per minute to an object that is to be polished relative to an area that is to be polished of the object that is to be polished (substrate wafer area).

In the chemical mechanical polishing method of the present invention, the flow rate per minute of the polishing liquid supplied to the object that is to be polished during polishing is 0.035 to 0.25 mL/(min·cm²), and is more preferably 0.100 to 0.25 mL/(min·cm²) from the viewpoint of preventing the temperature of the polishing liquid during processing from increasing excessively. It is undesirable if the polishing liquid flow rate is less than 0.035 mL/(min·cm²) since the temperature during processing increases excessively and good polishing results cannot be obtained. Furthermore, a flow rate of 0.25 mL/(min·cm²) or greater is undesirable in terms of cost and the environment.

### Barrier Metal

The object that is to be polished (target for polishing) in the present invention is preferably, for example, a barrier layer (also called simply a ‘barrier’) that is provided between wiring and an interlayer insulating film and prevents wiring metal from diffusing in the production of a semiconductor.

In the polishing method of the present invention, as a barrier metal used for a barrier layer that can suitably be polished, a metal material with low electrical resistance is preferable, TiN, TiW, Ta, TaN, Ru, W, and WN are more preferable, and Ta and TaN are particularly preferable.

As hereinbefore described, the chemical mechanical polishing method of the present invention employs a barrier polishing liquid, can suitably be applied to polishing of barrier metal in a semiconductor such as an LSI, and can also suitably be applied to polishing of metal wiring at the same time as polishing a barrier layer, that is, the polishing method of the present invention can suitably polish metal wiring.

Furthermore, needless to say, accompanying polishing of the barrier metal or metal wiring the chemical mechanical polishing method of the present invention may partially polish a silicon substrate, silicon oxide, silicon nitride, a resin, carbon wiring, precious metal wiring, an insulating film, etc. by virtue of the effect of the acid, abrasive grains, etc.

### Wiring Metal Starting Material

The polishing method of the present invention enables metal wiring to be suitably polished, and the metal wiring is preferably, for example, wiring formed from copper metal and/or a copper alloy on a semiconductor such as an LSI, and particularly preferably a copper alloy. Furthermore, among copper alloys a copper alloy containing silver is preferable. The silver content of the copper alloy is preferably no greater than 40 wt %, particularly preferably no greater than 10 wt %, and more preferably no greater than 1 wt %, and the best effects can be exhibited when the content thereof in the copper alloy is in the range of 0.00001 to 0.1 wt %.

### Thickness of Wiring

The semiconductor to which the polishing method of the present invention can be applied is preferably an LSI having wiring with a half-pitch of 0.15 μm or less for a DRAM device, more preferably 0.10 μm or less, and yet more preferably 0.08 μm or less. In the case of an MPU device, it is preferably an LSI having wiring of 0.12 μm or less, more preferably 0.09 μm or less, and yet more preferably 0.07 μm or less. The chemical mechanical polishing method of the present invention exhibits particularly superior effects toward these DRAMs and LSIs.

### Pad

A polishing pad for polishing may be either a pad with a non-foamed structure or a pad with a foamed structure. The former employs a rigid synthetic resin bulk material such as a plastic board as a pad. The latter is further classified into three types, that is, a closed cell type (dry foam type), an open cell type (wet foam type), and a two layer composite type (laminated type), and the two layer composite type (laminated type) is particularly preferable. The foam may be uniform or nonuniform.

Furthermore, the pad may contain abrasive grains (e.g. ceria, silica, alumina, resin, etc.). With regard to the hardness, there are a soft type and a rigid type; either may be used, and it is preferable for each layer of the laminated type to have different hardness. The material thereof is preferably nonwoven fabric, artificial leather, polyamide, polyurethane, polyester, polycarbonate, etc. The surface that is in contact with the polishing surface may be subjected to machining to form grid channels, holes, concentric channels, spiral channels, etc.

### Wafer

It is preferable for a wafer as an object to be polished in the chemical mechanical polishing method of the present invention to have a diameter of 200 mm or greater, and particularly preferably 300 mm or greater. The effects of the present invention can be exhibited remarkably when the diameter is 300 mm or greater.

In accordance with the present invention, there can be provided a barrier polishing liquid that enables polishing to proceed at a sufficient polishing rate and dishing to be suppressed in chemical mechanical polishing of a semiconductor device film, etc. that is to be processed.

Furthermore, in accordance with the present invention, there can be provided a chemical mechanical polishing method that, in chemical mechanical polishing of a semiconductor device film, etc. that is to be processed, enables polishing to proceed at a sufficient polishing rate with the use of a small amount of polishing liquid, dishing to be suppressed, and the cost to be sufficiently suppressed in actual use.

### EXAMPLES

The present invention is explained in further detail below by reference to Examples, but the present invention should not be construed as being limited to these Examples.

### Example 1

The polishing liquid shown below was prepared and a polishing evaluation was carried out using a polishing system that will be described later.

### Preparation of Polishing Liquid

A polishing liquid was prepared by mixing the composition below.

| | | |
|---|---|---|
| Colloidal silica | 50 | g/L |
| Ammonium benzoate (organic acid, | 10 | g/L |
| manufactured by Wako Pure | | |
| Chemical Industries, Ltd.) | | |
| BTA (benzotriazole) (aromatic ring | 1 | g/L |
| compound) | | |
| Surfynol 104E (nonionic surfactant, | 1 | g/L |
| manufactured by Nissin Chemical | | |
| Industry Co., Ltd.) | | |
| Pure water | to make a total of 1,000 | mL |
| pH (adjusted with aqueous ammonia | 3.0 | |
| and sulfuric acid) | | |

### Polishing Conditions

A film provided on each wafer was polished while supplying a slurry under the conditions below using a ‘FREX-300’ manufactured by Ebara Corporation as a polishing system, and the polishing rate was determined. Substrate: a 12 inch copper film-equipped silicon wafer obtained by subjecting Black Diamond to patterning in a photolithographic step and a reactive ion etching step to form a via hole and a wiring groove having a width of 0.09 to 100 μm and a depth of 600 nm, further to sputtering to form a Ta film having a thickness of 20 nm, subsequently to sputtering to form a copper film having a thickness of 50 nm, and then to plating to give a copper film having a total thickness of 1,000 nm

Table rotational speed: 104 rpm
Head rotational speed: 105 rpm
(processing line speed=1.0 m/s)
Polishing pressure: 105 hPa
Polishing pad: Product No. IC-1400 (K-grv)+(A21) manufactured by Rohm and Haas
Polishing liquid supply rate: 150 mL/min (0.14 mL/min·cm²)

### Evaluation Method

### 1) Insulating Film Polishing Rate

Black Diamond was used as an insulating film.

The polishing rate was calculated from film thicknesses before and after polishing using the equation below.

polishing rate (nm/min)=(thickness of insulating film before polishing−thickness of insulating film after polishing)/polishing time Equation

### 2) Evaluation of Dishing

A wafer obtained by subjecting a pattern wafer to a 1st polishing for a time until copper in nonwiring areas was completely polished plus a time corresponding; to 50% of the above time (dishing after 1st: line 100 μm/space 100 μm 60 nm). This wafer was polished with each slurry for 30 sec, and dishing of the wafer (line 100 μm/space 100 μm) was measured using a Dektak V320Si stylus profiler (manufactured by Veeco).

### Examples 2 to 21 and Comparative Examples 1 and 2

Polishing tests of Examples 2 to 21 and Comparative Examples 1 and 2 were carried out under polishing conditions described in Table 1 and Table 2 employing the same conditions as those of Example 1 except for the nonionic surfactant, the organic acid, and the corrosion inhibitor. The results are given in Table 1 and Table 2.

TABLE 1

| | | | | | | Polishing | Insulating | |
|---|---|---|---|---|---|---|---|---|
| | | | | | Polishing | liquid | film | |
| | Nonionic | | Corrosion | Polishing | liquid | supply | polishing | |
| | surfactant | | inhibitor | pressure | flow rate | rate | rate | Dishing |
| | (g/L) | Organic acid (g/L) | (g/L) | (KPa) | (mL/min · cm²) | (mL/min) | (nm/min) | (nm) |
| Ex. 1 | Surfynol | Ammonium | BTA (1) | 13.79 | 0.14 | 150 | 55 | 45 |
| | 104E (1) | benzoate (10) | | | | | | |
| Ex. 2 | Surfynol | Phthalic acid (10) | DBTA (1) | 13.79 | 0.21 | 150 | 45 | 35 |
| | 104E (1) | | | | | | | |
| Ex. 3 | Surfynol | Ammonium | HEABTA | 13.79 | 0.14 | 100 | 48 | 35 |
| | 420 (1) | benzoate (10) | (1.5) | | | | | |
| Ex. 4 | Surfynol | 1,2,3-Benzene- | BTA (1) | 13.79 | 0.14 | 100 | 50 | 40 |
| | 104A (1) | tricarboxylic acid | | | | | | |
| | | (12) | | | | | | |
| Ex. 5 | Surfynol | 1,2,4,5- | DBTA (1) | 13.79 | 0.21 | 150 | 52 | 42 |
| | 465 (1) | Benzenetetra- | | | | | | |
| | | carboxylic acid | | | | | | |
| | | (14) | | | | | | |
| Ex. 6 | Surfynol | p-Toluenesulfonic | HMBTA | 13.79 | 0.07 | 50 | 49 | 41 |
| | 420 (1) | acid (12) | (1.2) | | | | | |
| Ex. 7 | Surfynol | Phthalic acid (10) | HMBTA | 13.79 | 0.14 | 100 | 50 | 38 |
| | 104E (1) | | (1.2) | | | | | |
| Ex. 8 | Surfynol | Ammonium | DCEBTA | 13.79 | 0.21 | 150 | 52 | 45 |
| | 485 (1) | benzoate (10) | (1.5) | | | | | |
| Ex. 9 | Surfynol | 1,2,3-Benzenetri- | HEABTA | 13.79 | 0.21 | 150 | 55 | 46 |
| | 420 (1) | carboxylic acid | (1.5) | | | | | |
| | | (12) | | | | | | |
| Ex. | Surfynol | Ammonium | BTA (1) | 13.79 | 0.14 | 100 | 50 | 44 |
| 10 | 420 (1) | benzoate (10) | | | | | | |
| Ex. | Surfynol | p-Toluenesulfonic | HEABTA | 10.34 | 0.21 | 150 | 48 | 43 |
| 11 | 104E (1) | acid (12) | (1.5) | | | | | |
| Ex. | Surfynol | 1,2,4,5- | HMBTA | 10.34 | 0.07 | 50 | 42 | 40 |
| 12 | 485 (1) | Benzenetetra- | (1.2) | | | | | |
| | | carboxylic acid | | | | | | |
| | | (14) | | | | | | |

TABLE 2

| | | | | | | | Insulating | |
|---|---|---|---|---|---|---|---|---|
| | | | | | Polishing | Polishing | film | |
| | Nonionic | | Corrosion | Polishing | liquid | liquid | polishing | |
| | surfactant | Organic acid | inhibitor | pressure | flow rate | supply rate | rate | Dishing |
| | (g/L) | (g/L) | (g/L) | (KPa) | (mL/min · cm²) | (mL/min) | (nm/min) | (nm) |
| Ex. 13 | Surfynol | Phthalic | DCEBTA | 10.34 | 0.14 | 100 | 40 | 35 |
| | 104E (1) | acid (10) | (1.5) | | | | | |
| Ex. 14 | Surfynol | Ammonium | HEABTA | 10.34 | 0.21 | 150 | 42 | 42 |
| | 104A (1) | benzoate | (1.5) | | | | | |
| | | (10) | | | | | | |
| Ex. 15 | Surfynol | Ammonium | BTA (1) | 10.34 | 0.07 | 50 | 38 | 39 |
| | 485 (1) | benzoate | | | | | | |
| | | (10) | | | | | | |
| Ex. 16 | Surfynol | p-Toluene- | BTA (1) | 10.34 | 0.07 | 50 | 41 | 42 |
| | 420 (1) | sulfonic acid | | | | | | |
| | | (12) | | | | | | |
| Ex. 17 | Surfynol | 1,2,4,5- | DBTA (1) | 10.34 | 0.14 | 100 | 40 | 50 |
| | 465 (1) | Benzene- | | | | | | |
| | | tetracarboxylic | | | | | | |
| | | acid | | | | | | |
| | | (14) | | | | | | |
| Ex. 18 | Surfynol | Ammonium | DCEBTA | 10.34 | 0.21 | 150 | 38 | 38 |
| | 104E (1) | benzoate | (1.5) | | | | | |
| | | (10) | | | | | | |
| Ex. 19 | Surfynol | 1,2,3- | BTA (1), | 10.34 | 0.21 | 150 | 40 | 45 |
| | 420 (1) | Benzene- | DBTA (1) | | | | | |
| | | tricarboxylic | | | | | | |
| | | acid (12) | | | | | | |
| Ex. 20 | Surfynol | p-Toluene- | BTA (1) | 10.34 | 0.21 | 150 | 42 | 40 |
| | 104A (1) | sulfonic acid | | | | | | |
| | | (12) | | | | | | |
| Ex. 21 | Surfynol | Phthalic | DBTA (1), | 10.34 | 0.21 | 150 | 40 | 45 |
| | 104E (1) | acid (10) | HEABTA | | | | | |
| | | | (1.5) | | | | | |
| Comp. | None | Glycine (8) | DCEBTA | 13.79 | 0.21 | 150 | 20 | 200 |
| Ex. 1 | | | (1.5), BTA | | | | | |
| | | | (1) | | | | | |
| Comp. | Surfynol | Glycine (8) | BTA (1) | 13.79 | 0.21 | 150 | 8 | 280 |
| Ex. 2 | 104E (1) | | | | | | | |

In Table 1 and Table 2 above, figures in parentheses denote the amount used. Furthermore, in Table 1 and Table 2 above, the abbreviations below were used. The corresponding compounds are shown below.

### BTA=1,2,3-benzotriazole

### DBTA=5,6-dimethyl-1,2,3-benzotriazole

### HEABTA=1-[N,N-bis(hydroxyethyl)aminomethyl]benzotriazole

### HMBTA=1-(hydroxymethyl)benzotriazole

DCEBTA=1-(1,2-dicarboxyethyl)benzotriazole

What is claimed is:

1. A barrier polishing liquid comprising:
(a) a nonionic surfactant represented by Formula (I) below;
(b) at least one type of organic acid selected from the group consisting of an aromatic sulfonic acid, an aromatic carboxylic acid, and a derivative thereof;
(c) colloidal silica; and
(d) benzotriazole or a derivative thereof, 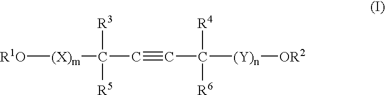
wherein R¹ to R⁶ independently denote a hydrogen atom or an alkyl group having 1 to 10 carbons, X and Y independently denote an ethyleneoxy group or a propyleneoxy group, and m and n independently denote an integer of 0 to 20.

2. The barrier polishing liquid according to claim 1, wherein the nonionic surfactant represented by Formula (I) is a compound represented by W-1 or W-2 below, 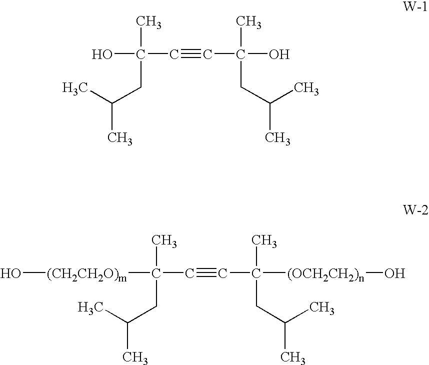
wherein m and n independently denote an integer of 1 to 20.

3. The barrier polishing liquid according to claim 1, wherein the amount of nonionic surfactant represented by Formula (I) added is 0.01 to 5 wt % relative to the total weight of the barrier polishing liquid.

4. The barrier polishing liquid according to claim 1, wherein the organic acid is a compound selected from the group consisting of p-toluenesulfonic acid, ammonium benzoate, phthalic acid, 1,2,4,5-benzenetetracarboxylic acid, and 1,2,3-benzenetricarboxylic acid.

5. The barrier polishing liquid according to claim 1, wherein the amount of organic acid added is 0.01 to 20 wt % relative to the total weight of the barrier polishing liquid.

6. The barrier polishing liquid according to claim 1, wherein the amount of colloidal silica added is 0.5 to 15 wt % relative to the total weight of the barrier polishing liquid.

7. The barrier polishing liquid according to claim 1, wherein the benzotriazole or a derivative thereof is a compound selected from the group consisting of 1,2,3-benzotriazole, 5,6-dimethyl-1,2,3-benzotriazole, 1-[N,N-bis(hydroxyethyl)aminomethyl]benzotriazole, 1-(hydroxymethyl)benzotriazole, and 1-(1,2-dicarboxyethyl)benzotriazole.

8. The barrier polishing liquid according to claim 1, wherein the amount of benzotriazole or a derivative thereof added is 0.01 to 0.2 wt % relative to the total weight of the barrier polishing liquid.

9. A chemical mechanical polishing method comprising:
supplying a barrier polishing liquid comprising at least
(a) a nonionic surfactant represented by Formula (I) below,
(b) at least one type of organic acid selected from the group consisting of an aromatic sulfonic acid, an aromatic carboxylic acid, and a derivative thereof,
(c) colloidal silica, and
(d) benzotriazole or a derivative thereof,
to a polishing pad on a polishing platen at a flow rate per unit area of a semiconductor substrate per unit time of 0.035 to 0.25 mL/(min·cm²); and
polishing by making the polishing pad and a surface to be polished move relative to each other while they are in a contacted state, 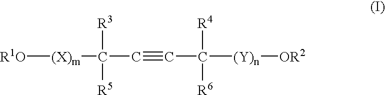
wherein R¹ to R⁶ independently denote a hydrogen atom or an alkyl group having 1 to 10 carbons, X and Y independently denote an ethyleneoxy group or a propyleneoxy group, and m and n independently denote an integer of 0 to 20.

10. The chemical mechanical polishing method according to claim 9, wherein an object that is to be polished is a semiconductor substrate having a barrier layer.

11. The chemical mechanical polishing method according to claim 9, wherein the nonionic surfactant represented by Formula (I) is a compound represented by W-1 or W-2 below, 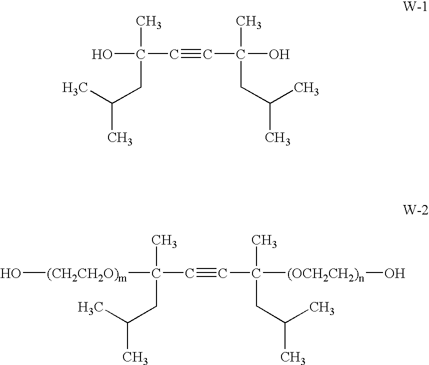
wherein m and n independently denote an integer of 1 to 20.

12. The chemical mechanical polishing method according to claim 9, wherein the amount of nonionic surfactant represented by Formula (I) added is 0.01 to 5 wt % relative to the total weight of the barrier polishing liquid.

13. The chemical mechanical polishing method according to claim 9, wherein the organic acid is a compound selected from the group consisting of p-toluenesulfonic acid, ammonium benzoate, phthalic acid, 1,2,4,5-benzenetetracarboxylic acid, and 1,2,3-benzenetricarboxylic acid.

14. The chemical mechanical polishing method according to claim 9, wherein the amount of organic acid added is 0.01 to 20 wt % relative to the total weight of the barrier polishing liquid.

15. The chemical mechanical polishing method according to claim 9, wherein the amount of colloidal silica added is 0.5 to 15 wt % relative to the total weight of the barrier polishing liquid.

16. The chemical mechanical polishing method according to claim 9, wherein the benzotriazole or a derivative thereof is a compound selected from the group consisting of 1,2,3-benzotriazole, 5,6-dimethyl-1,2,3-benzotriazole, 1-[N,N-bis(hydroxyethyl)aminomethyl]benzotriazole, 1-(hydroxymethyl)benzotriazole, and 1-(1,2-dicarboxyethyl)benzotriazole.

17. The chemical mechanical polishing method according to claim 9, wherein the amount of benzotriazole or a derivative thereof added is 0.01 to 0.2 wt % relative to the total weight of the barrier polishing liquid.
